(19) United States
(12) Patent Application Publication
(10) Pub. No.: US 2025/0228118 A1
(43) Pub. Date: Jul. 10, 2025

(54) LIGHT-EMITTING ELEMENT AND MANUFACTURING METHOD THEREFOR, DISPLAY DEVICE, AND NICKEL OXIDE NANO-PARTICLE DISPERSION

(71) Applicant: Sharp Display Technology Corporation, Kameyama City, Mie (JP)

(72) Inventors: HISAYUKI UTSUMI, Kameyama City, Mie (JP); Masayuki KANEHIRO, Kameyama City, Mie (JP)

(21) Appl. No.: 18/852,757

(22) PCT Filed: May 30, 2022
(86) PCT No.: PCT/JP2022/021985

§ 371 Date: Sep. 30, 2024

(51) Int. Cl. H10K 85/10; H10K 50/115; H10K 50/15; H10K 50/17; H10K 59/12; H10K 59/35; H10K 71/15; H10K 102/00

(52) U.S. Cl. CPC H10K 85/10; H10K 50/17; H10K 50/115; H10K 50/15; H10K 59/1201; H10K 59/35; H10K 71/15; H10K 2102/331

(57) ABSTRACT

A light-emitting element includes an anode electrode, a cathode electrode, an EML provided therebetween, and an HIL provided between the anode electrode and the EML, the HIL including a NiO-NP and a PVP.

### TECHNICAL FIELD

The disclosure relates to a light-emitting element, a manufacturing method therefor, a display device, and a nickel oxide nanoparticle dispersion.

### BACKGROUND ART

In many cases, a hole injection layer is provided between an anode electrode and a light-emitting layer in a self-luminous light-emitting element in order to promote injection of holes from the anode electrode to the light-emitting layer. A complex of PEDOT (poly(3,4-ethylenedioxythiophene)) and PSS (poly(4-styrenesulfonic acid)), referred to as PEDOT:PSS, has been generally used for the hole injection layer. PEDOT:PSS has an excellent hole injection property and high solubility in an aqueous solvent, and thus can be easily formed into a layer by a liquid phase film formation method.

However, PEDOT:PSS causes degradation of light-emission characteristics such as external quantum efficiency (EQE) over time.

Therefore, in recent years, it has been proposed to use nickel oxide nanoparticles in the hole injection layer instead of PEDOT:PSS (for example, see PTL 1). Nickel oxide is a P-type oxide semiconductor material and has the hole injection property.

### CITATION LIST

### Patent Literature

PTL 1: WO 2018/001372

### SUMMARY

### Technical Problem

However, nickel oxide nanoparticles tend to aggregate due to their small particle size, and solvents and additives suitable for nickel oxide nanoparticles have not been found, and their dispersibility in solvents is low. Therefore, when the hole injection layer is formed by, for example, spin coating (spinner coating) the nickel oxide nanoparticle dispersion containing the nickel oxide nanoparticles, the film formability of the hole injection layer is poor, and the formed hole injection layer is uneven and flatness is not ensured. As a result, the movement of holes in the hole injection layer seems to be biased, and it is highly likely that uniform light emission is not obtained.

Note that the work function of the nickel oxide thin film is larger than the work function of, for example, Indium Tin Oxide (ITO) used for the anode electrode, but smaller than the absolute value of the energy level of the Highest Occupied Molecular Orbital (HOMO) or the upper end of the valence band of most organic hole transport materials.

Therefore, in PTL 1, an organic molecule having an electron-withdrawing group, such as trifluoromethyl benzoic acid, trifluoromethyl phenylacetic acid, or trifluorobutyric acid, is bonded to the surface of the nickel oxide thin film to improve the hole injection property of the hole injection layer.

For this purpose, in PTL 1, first, a nickel oxide precursor liquid or a nickel oxide liquid produced in advance, which contains, for example, lithium stearate as a ligand (dispersing agent), is applied onto a substrate on which a conductive film is provided. Then, an annealing treatment is performed at 130 to 300° C. for 10 to 90 minutes to form a nickel oxide thin film. Thereafter, an organic molecule solution obtained by dissolving an organic molecule having an electron-withdrawing group in a solvent is applied to the surface of the nickel oxide thin film and annealed at 80 to 180° C. for 1 to 60 minutes to form a hole injection layer in which the organic molecule is bonded to the surface of the nickel oxide thin film. Preferably, in order to promote the chemical bonding between the organic molecules and the nickel atoms, before the application of the organic molecule solution, for example, ultraviolet ozone treatment is performed to remove the ligands and expose the nickel atoms. Therefore, in the method described in PTL 1, the process treatment is complicated and takes a long time.

An aspect of the disclosure has been made in view of the above-described problems, and an object thereof is to provide a light-emitting element and a manufacturing method for the light-emitting element that includes a hole injection layer having good film formability, an improved hole injection property, high flatness, and high strength, and can easily form such a hole injection layer, a display device, and a nickel oxide nanoparticle dispersion capable of forming such a hole injection layer.

### Solution to Problem

In order to solve the above problems, a light-emitting element according to an aspect of the disclosure includes an anode electrode, a cathode electrode, a light-emitting layer provided between the anode electrode and the cathode electrode, and a hole injection layer provided between the anode electrode and the light-emitting layer, the hole injection layer including a nickel oxide nanoparticle and polyvinylpyrrolidone.

In order to solve the above problems, a display device according to an aspect of the disclosure includes a plurality of the light-emitting elements according to an aspect of the disclosure.

In order to solve the above problems, a nickel oxide nanoparticle dispersion according to an aspect of the disclosure includes a nickel oxide nanoparticle, polyvinylpyrrolidone, and a solvent.

In order to solve the above problems, according to an aspect of the disclosure, there is provided a manufacturing method for a light-emitting element including an anode electrode, a cathode electrode, a light-emitting layer provided between the anode electrode and the cathode electrode, and a hole injection layer provided between the anode electrode and the light-emitting layer, the method including a hole injection layer forming step of forming the hole injection layer, the hole injection layer forming step including a step of applying a nickel oxide nanoparticle dispersion containing a nickel oxide nanoparticle, polyvinylpyrrolidone, and a solvent, and a step of removing the solvent contained in the nickel oxide nanoparticle dispersion.

### Advantageous Effects of Disclosure

According to an aspect of the disclosure, it is possible to provide a light-emitting element and a manufacturing method for the light-emitting element that includes a hole injection layer having good film formability, an improved hole injection property, high flatness, and high strength, and can easily form such a hole injection layer, a display device, and a nickel oxide nanoparticle dispersion capable of forming such a hole injection layer.

### BRIEF DESCRIPTION OF DRAWINGS

FIG. 1 is a cross-sectional view illustrating an example of a schematic configuration of a light-emitting element according to an aspect of an embodiment.

FIG. 2 is a schematic view illustrating an example of a nickel oxide nanoparticle dispersion according to an aspect of the embodiment.

FIG. 3 is a flowchart illustrating an example of a manufacturing method for the light-emitting element according to an aspect of the embodiment.

FIG. 4 is a cross-sectional view schematically illustrating a structure of a hole injection layer on an anode electrode in a light-emitting element for comparison in which a hole injection layer does not contain polyvinylpyrrolidone.

FIG. 5 is a cross-sectional view illustrating an example of a schematic configuration of a display device according to an aspect of the embodiment.

### DESCRIPTION OF EMBODIMENTS

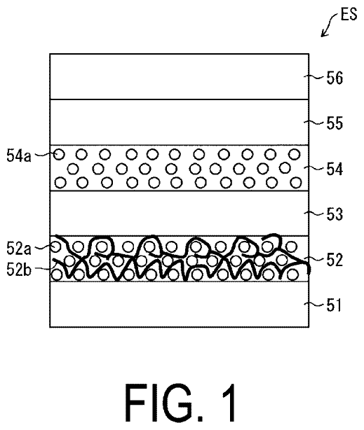

A description follows regarding an embodiment of the disclosure with reference to FIG. 1 to FIG. 4. Note that in the following description, a “lower layer” means a layer that is formed in a process preceding a process in which a layer for comparison is formed, while an “upper layer” means a layer that is formed in a process following a process in which a layer for comparison is formed. In the following description, a description of “from A to B” for two numbers A and B means “equal to or greater than A and equal to or less than B”, unless otherwise specified.

The light-emitting element according to the present embodiment includes an anode electrode, a cathode electrode, a light-emitting layer provided between the anode electrode and the cathode electrode, and a hole injection layer provided between the anode electrode and the light-emitting layer. The light-emitting element according to the present embodiment is a quantum dot light-emitting diode (QLED) including a quantum dot light-emitting layer containing a quantum dot as the light-emitting layer.

In the present embodiment, the layers between the anode electrode and the cathode electrode are collectively referred to as a function layer. As function layers other than the hole injection layer and the light-emitting layer, for example, a hole transport layer may be provided between the hole injection layer and the light-emitting layer, and an electron transport layer may be provided between the light-emitting layer and the cathode electrode. In addition, although not described, another function layer may be further provided between the anode electrode and the cathode electrode. Hereinafter, the quantum dot is referred to as “QD”, the light-emitting layer is referred to as “EML”, and the hole injection layer is referred to as “HIL”. In addition, the hole transport layer is referred to as “HTL”, and the electron transport layer is referred to as “ETL”.

FIG. 1 is a cross-sectional view illustrating an example of a schematic configuration of a light-emitting element ES according to the present embodiment.

The light-emitting element ES illustrated in FIG. 1 has a configuration in which an anode electrode 51, an HIL 52, an HTL 53, an EML 54, an ETL 55, and a cathode electrode 56 are layered in this order from the lower layer side.

Note that FIG. 1 illustrates a case where the light-emitting element ES has a known structure in which the anode electrode 51 is the lower layer electrode and the cathode electrode 56 is the upper layer electrode. However, the light-emitting element ES according to the present embodiment is not limited thereto and may have an inverted structure in which the cathode electrode 56 is the lower layer electrode and the anode electrode 51 is the upper layer electrode. In this case, the layering order of the function layers is reversed compared with FIG. 1. That is, the light-emitting element ES may have a configuration in which the cathode electrode 56, the ETL 55, the EML 54, the HTL 53, the HIL 52, and the anode electrode 51 are layered in this order from the lower layer side.

The anode electrode 51 is formed on a substrate (not illustrated). The substrate is a support body that supports each layer from the anode electrode 51 to the cathode electrode 56, and each layer from the anode electrode 51 to the cathode electrode 56 is generally formed on the substrate used as a support body. Accordingly, the light-emitting element ES may include the substrate as a support body.

The substrate may be, for example, a rigid inorganic substrate such as a glass substrate, or a flexible substrate containing a resin such as polyimide as a main component. The substrate may be provided with a TFT (thin film transistor), a capacitance element, and the like (not illustrated).

The anode electrode 51 is an electrode that supplies holes to the EML 54 when a voltage is applied. The cathode electrode 56 is an electrode that supplies electrons to the EML 54 when a voltage is applied. The anode electrode 51 and the cathode electrode 56 each contain a conductive material and are connected to a power supply (not illustrated), whereby a voltage is applied therebetween.

Of the anode electrode 51 and the cathode electrode 56, the electrode on the light extraction face side in the light-emitting element ES needs to be transparent. The anode electrode 51 and the cathode electrode 56 may each be a single layer or may each have a layered structure.

For example, in a case where the light-emitting element ES is a top-emission type display element that extracts light from the side of the upper layer electrode that is provided on the opposite side of the substrate, a light-transmissive electrode that is transparent is used as the upper layer electrode, and for example, a so-called reflective electrode having light reflectivity is used as the lower layer electrode.

On the other hand, in a case where the light-emitting element ES is a bottom-emission type display element that extracts light from the side of the lower layer electrode that is provided on the substrate side, a light-transmissive electrode is used as the lower layer electrode, and a reflective electrode is used as the upper layer electrode.

The light-transmissive electrode is formed of a light-transmissive material such as a thin film of ITO, indium zinc oxide (IZO), silver nanowire (AgNW), a magnesium-silver (MgAg) alloy, or a thin film of silver (Ag), for example.

The reflective electrode may be formed of a light-reflective material, for example, a metal such as Ag or aluminum (Al), or an alloy containing these metals, and may be the reflective electrode obtained by layering a light-transmissive material and a light-reflective material. Therefore, the reflective electrode may have a layered structure such as ITO/Ag alloy/ITO, ITO/Ag/ITO, or Al/IZO.

The EML 54 is a layer that includes a light-emitting material and emits light by recombination of holes transported from the anode electrode 51 and electrons transported from the cathode electrode 56. The EML 54 is a QD light-emitting layer as described above and contains a nano-sized QD 54a corresponding to a luminescent color as a light-emitting material.

The QD 54a is a dot including nanoparticles with a maximum width of 100 nm or less. QDs generally have a composition derived from a semiconductor material, and thus may also be called semiconductor nanoparticles. Furthermore, since QDs have a specific crystal structure, for example, they may also be called nanocrystals.

The shape of the QD 54a is not particularly limited as long as it is within a range satisfying the maximum width, and the shape thereof is not limited to a spherical three-dimensional shape (circular cross-sectional shape). The shape thereof may be, for example, a polygonal cross-sectional shape, a rod-shaped three-dimensional shape, a branch-shaped three-dimensional shape, or a three-dimensional shape having unevenness on the surface thereof, or a combination thereof.

The QD 54a may be of a core type, a core-shell type including a core and a shell, or a core-multi-shell type. In a case where the QD 54a includes the shell, it is sufficient for the shell to be provided on the surface of the core, the core being centrally located. Although it is desirable for the shell to cover the entire core, the shell need not necessarily completely cover the core. Further, the QD 54a may be a two-component core type, a three-component core type, or a four-component core type. Note that the QD 54a may include doped nanoparticles or may have a compositionally graded structure.

The core may be formed of, for example, Si, Ge, CdSe, CdS, CdTe, InP, GaP, InN, ZnSe, ZnS, ZnTe, CdSeTe, GaInP, ZnSeTe, or the like. The shell may be formed of, for example, CdS, ZnS, CdSSe, CdTeSe, CdSTe, ZnSSe, ZnSTe, ZnTeSe, AIP, or the like.

A light emission wavelength of the QD 54a can be changed in various ways depending on the particle diameter, the composition thereof, or the like. The QD 54a is a QD that emits visible light, and, for example, red light, green light, and blue light can be achieved by appropriately adjusting the particle diameter and composition of the QD 54a.

Here, before describing the HIL 52, the ETL 55 and the HTL 53 will be described. Note that the HIL 52 will be described below in detail.

The ETL 55 is a charge transport layer including an electron transport material and having an electron transport function of increasing an electron transport efficiency to the EML 54. Examples of the electron transport material include N-type oxide semiconductor nanoparticles such as ZnO nanoparticles and MgZnO nanoparticles. Since these N-type oxide semiconductor nanoparticles have excellent electron injection property, the electron injection layer is often omitted as illustrated in FIG. 1.

The HTL 53 is a charge transport layer containing a hole transport material and having a hole transport function of increasing hole transport efficiency to the EML 54. Examples of the hole transport material include, for example, poly[(9,9-dioctylfluorenyl-2,7-diyl)-co-(4,4′-(N-4-sec-butylphenyl)) diphenylamine)] (referred to as “TFB”), poly[N,N′-bis(4-butylphenyl)-N,N′-bis(phenyl)-benzidine] (referred to as “p-TPD”), polyvinyl carbazole (referred to as “PVK”), and the like.

### (HIL 52)

Next, the HIL 52 will be described in detail.

The HIL 52 is a charge injection layer containing a hole transport material and having a hole injection function of promoting injection of holes from the anode electrode 51 into the EML 54. The HIL 52 contains a nickel oxide nanoparticle (hereinafter referred to as “NiO-NP”) 52a and a polyvinylpyrrolidone (hereinafter referred to as “PVP”) 52b.

However, in the disclosure, the molar ratio between nickel atoms and oxygen atoms in nickel oxide is not limited to 1:1, and nickel oxide is not limited to NiO. The nickel oxide used in the disclosure may be nickel oxide composed of various molar ratios, and the nickel oxide refers to a nickel oxide nanocrystal.

The NiO-NP 52a is a hole transport material for increasing the hole injection efficiency from the anode electrode 51 to the HTL 53. The PVP 52b functions as a binder resin for binding the NiO-NPs 52a to each other. The NiO-NP 52a and the PVP 52b are integrated as the HIL 52. The PVP 52b also functions as a dispersing agent and enters between the NiO-NPs 52a to enhance the dispersibility of the NiO-NP 52a. Therefore, the NiO-NP 52a is dispersed in the PVP 52b.

The QLED generally uses N-type oxide semiconductor nanoparticles, such as ZnO nanoparticles or MgZnO nanoparticles, having excellent electron injection property for the ETL, as described above. Therefore, the QLED generally tends to have a lower hole injection property than the electron injection property. Thus, generally, the amount of electrons injected is greater than the amount of holes injected in the EML, so that there has been a problem of excessive electron supply and shortage of holes. When there is a large difference between the amount of hole injected and the amount of electron injected in the EML, the luminous efficiency decreases.

In addition, in the case of the QLED, the work function of the nickel oxide thin film is smaller than the absolute value of the energy level at the upper end of the valence band of most organic hole transport materials, as described above. Moreover, the ITO needs to overcome a relatively high barrier when injecting holes as an anode electrode. Therefore, it is desired to improve the hole injection property.

Under such circumstances, as described above, mixing of PVP, which is an insulating polymer, into the HIL 52 is usually not considered. However, as a result of studies conducted by the inventors of the present application, it has been found that when the HIL 52 contains the NiO-NP 52a and the PVP 52b, the film formability of the HIL 52 is improved, the highly flat and strong HIL 52 can be obtained, and the EQE (external quantum efficiency) is improved. Further, such an HIL 52 does not require a complicated and time-consuming process treatment as in PTL 1.

Note that as described above, since the HIL 52 contains the NiO-NP 52a and the PVP 52b, the above-described effect can be obtained. However, as described above, the PVP 52b is an insulator. Therefore, in the HIL 52, hole movement occurs by hopping conduction of holes due to the tunneling effect. The tunneling current between the NiO-NPs 52a covered with an insulator such as the PVP 52b is more likely to occur as the distance between the NiO-NPs 52a becomes shorter. The tunneling current is generated when the distance between the NiO-NPs 52a is equal to or less than 3 nm. Note that the tunneling current is likely to occur when the distance between the NiO-NPs 52a is equal to or less than 2 nm and is particularly likely to occur when the distance is equal to or less than 1.5 nm.

The NiO-NP 52a and the PVP 52b may be mixed so as to generate the tunneling current. In particular, when the NiO-NP 52a and the PVPs 52b are mixed so that the mean value of the distance between the NiO-NPs 52a per unit area is within the above-described range, a sufficient tunneling current can flow. As a result, it is possible to sufficiently suppress the higher voltage due to mixing of the PVP 52b, which is an insulator.

However, when the amount of PVP contained in the HIL 52 is too small, the effect of the addition of the PVP may not be sufficiently obtained. In addition, even if the tunneling current can flow, when the amount of the NiO-NP 52a contained in the HIL 52 is too small, the hole-transporting external quantum efficiency (EQE) decreases.

Therefore, the volume ratio of the NiO-NP 52a to the PVP 52b (NiO-NP/PVP) in the HIL 52 is desirably 40/60 or more and 95/5 or less. In other words, the volume ratio of the NiO-NP 52a to the total amount of the NiO-NP 52a and the PVP 52b in the HIL 52 is desirably equal to or greater than 40 vol % and equal to or less than 95 vol %. As such, when the volume ratio of NiO-NP/PVP is 40/60 or more as described above, the external quantum efficiency (EQE) of 5.0% or more can be obtained as shown in Examples to be described later. Furthermore, in order to sufficiently obtain the effect of addition of PVP, the volume ratio of NiO-NP/PVP is desirably 95/5 or less.

In addition, the volume ratio of NiO-NP/PVP is more desirably 80/20 or less from the viewpoint of film formability. Therefore, the volume ratio of NiO-NP/PVP is more desirably 40/60 or more and 80/20 or less. In other words, the volume ratio of the NiO-NP 52a to the total amount of the NiO-NP 52a and the PVP 52b in the HIL 52 is desirably equal to or greater than 40 vol % and equal to or less than 80 vol %. As described above, when the surface of the HIL is uneven, the light emission of the light-emitting element becomes non-uniform. By setting the volume ratio of NiO-NP/PVP to 80/20 or less, the film formability of the HIL 52 is improved, and it is possible to obtain the light-emitting element ES in which the flatness of the HIL 52 is higher, and uniform light emission is achieved, as shown in Examples to be described later.

In addition, the volume ratio of NiO-NP/PVP is more desirably 60/40 or more and 95/5 or less, and particularly desirably 60/40 or more and 80/20 or less from the viewpoint of EQE. In other words, the volume ratio of the NiO-NP 52a to the total amount of the NiO-NP 52a and the PVP 52b in the HIL 52 is more desirably equal to or greater than 60 vol % and equal to or less than 95 vol %, and particularly desirably equal to or greater than 60 vol % and equal to or less than 80 vol %.

By setting the volume ratio of NiO-NP/PVP to 60/40 or more and 95/5 or less as described above, even though the HIL 52 contains PVP which is an insulating polymer, surprisingly, high EQE can be obtained as compared with the case where the HIL 52 is composed of only NiO-NP as shown in Examples to be described later.

More surprisingly, by setting the volume ratio of NiO-NP/PVP to 60/40 or more and 80/20 or less, the EQE can be further improved. In addition, by setting the ratio of NiO-NP/PVP to 60/40 or more and 80/20 or less, as described above, the film formability of the HIL 52 is improved, and it is possible to obtain the light-emitting element ES in which the flatness of the HIL 52 is higher, and uniform light emission is achieved.

Note that, in the present embodiment, a “nanoparticle” refers to a particle having a nanometer size in volume median diameter (D50) (that is, less than 1 μm). The particle diameter of the NiO-NP 52a is not particularly limited as long as it is nano-sized but is preferably in a range from 8 nm to 20 nm in terms of volume median diameter (D50), for example.

When the particle diameter of the NiO-NP 52a (volume median diameter) is small, it tends to aggregate and the dispersibility in solvents is reduced, while the band gap is increased and the hole injection into the light-emitting material is easily facilitated. Therefore, the particle diameter (volume median diameter) of the NiO-NP 52a is preferably within the above range. Note that here, the volume median diameter (D50) refers to a particle diameter (cumulative average diameter) when a cumulative percentage in a volume-based cumulative particle size distribution is 50%.

In addition, the NiO-NP 52a more desirably has the volume median diameter (D50) corresponding to the luminescent color (light emission wavelength) of the light-emitting material.

For example, when the light-emitting element ES is a red light-emitting element that emits red light and red QDs that emit red light are used as the light-emitting material, the volume median diameter (D50) of the NiO-NP 52a is preferably in a range from 12 nm to 20 nm. In addition, when the light-emitting element ES is a green light-emitting element that emits green light and green QDs that emit green light are used as the light-emitting material, the volume median diameter (D50) of the NiO-NP 52a is preferably in a range from 10 nm to 16 nm. When the light-emitting element ES is a blue light-emitting element that emits blue light and blue QDs that emit blue light are used as the light-emitting material, the volume median diameter (D50) of the NiO-NP 52a is preferably in a range from 8 nm to 14 nm.

As described above, the particle diameter of the NiO-NP 52a has a particle diameter suitable for the luminescent color of the light-emitting material of the EML 54.

Note that a thickness of each of the layers in the light-emitting element ES is not particularly limited and may be set in a similar manner as a known manner. Therefore, the layer thickness of the HIL 52 is not particularly limited, and is preferably, for example, in a range from 20 nm to 30 nm. As a result, pinholes do not occur and the chromaticity (hue) of the luminescent color does not change.

Note that in the present embodiment, a nanoparticle diameter measuring device (model number: “Nanotrac Wave II-UT151”) manufactured by MicrotracBEL Corp. was used to measure the volume median diameter (D50). Pure water containing the NiO-NP 52a at a concentration of 30 mg/mL was used as a measurement sample. Frequency analysis by dynamic light scattering (DLS) was used for the analysis. The particle diameter was measured by taking out weak scattered light and a reference wave as an electric signal by a mixed (heterodyne method) photodetector, obtaining an FFT (Fast Fourier Transform) power spectrum from this signal, and performing frequency analysis.

The HIL 52 is formed by spin coating (spinner coating) a NiO-NP dispersion obtained by dispersing the NiO-NP 52a and the PVP 52b in a solvent on the anode electrode 51 which is a lower layer (underlayer) of the HIL 52.

### (NiO-NP Dispersion)

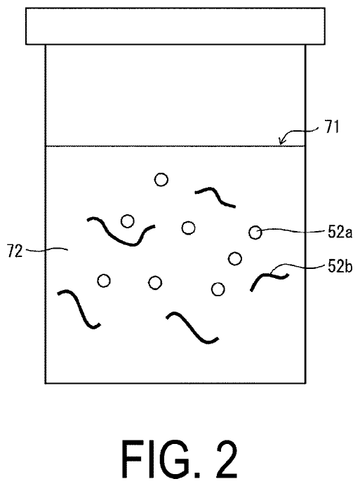

FIG. 2 is a schematic view illustrating an example of a NiO-NP dispersion 71 (nickel oxide nanoparticle dispersion) according to the present embodiment.

As illustrated in FIG. 2, the NiO-NP dispersion 71 according to the present embodiment contains the NiO-NP 52a, the PVP 52b, and a solvent 72 as a dispersion medium.

The NiO-NP dispersion 71 is a dispersion for forming the HIL 52 (a dispersion for forming a hole transport layer). The NiO-NP dispersion 71 is a so-called colloidal solution in which the NiO-NP 52a and the PVP 52b are dispersed in the solvent 72 until they become colloidal.

The NiO-NP dispersion 71 can be dispersed in an aqueous solvent or an organic solvent until it becomes colloidal. Therefore, the NiO-NP dispersion 71 is also dispersed in, for example, an ink solvent for an ink-jet coating device until it becomes colloidal.

For this reason, the solvent 72 may be an aqueous solvent or an organic solvent. As the solvent 72, an amphoteric solvent is preferably used, for example, water, alcohols such as methoxyethanol, glycols such as ethylene glycol, glycol ethers such as diethylene glycol monobutyl ether (butyl carbitol), and the like. Whereby, dispersion can be achieved.

The volume ratio (NiO-NP/PVP) of the NiO-NP 52a to the PVP 52b in the HIL 52 depends on the volume ratio (NiO-NP/PVP) of the NiO-NP 52a to the PVP 52b in the NiO-NP dispersion 71.

Therefore, the volume ratio of NiO-NP/PVP in the NiO-NP dispersion 71 is desirably 40/60 or more and 95/5 or less for the same reason as the volume ratio of NiO-NP/PVP in the HIL 52. Similarly, the volume ratio of NiO-NP/PVP in the NiO-NP dispersion 71 is more desirably 80/20 or less from the viewpoint of the film formability described above. Therefore, the volume ratio of NiO-NP/PVP in the NiO-NP dispersion 71 is more desirably 40/60 or more and 80/20 or less. In addition, the volume ratio of NiO-NP/PVP in the NiO-NP dispersion 71 is more desirably 60/40 or more and 95/5 or less and particularly desirably 60/40 or more and 80/20 or less from the viewpoint of the above-described EQE.

Furthermore, in the NiO-NP dispersion 71, the weight ratio of the NiO-NP 52a to the total amount of NiO-NP 52a and the PVP 52b is desirably equal to or greater than 78.9 wt % and equal to or less than 99.1 wt %. As a result, the volume ratio of NiO-NP/PVP in the HIL 52 can be 40/60 or more and 95/5 or less as shown in Examples to be described later. Then, as shown in Examples to be described later, by setting the weight ratio of the NiO-NP 52a to the total amount of the NiO-NP 52a and the PVP 52b in the NiO-NP dispersion 71 to equal to or greater than 78.9 wt % and equal to or less than 96.4 wt %, the volume ratio of NiO-NP/PVP in the HIL 52 can be 40/60 or more and 80/20 or less.

In addition, as shown in Examples to be described later, by setting the weight ratio of the NiO-NP 52a to the total amount of the NiO-NP 52a and the PVP 52b in the NiO-NP dispersion 71 to equal to or greater than 90.9 wt % and equal to or less than 99.1 wt %, the volume ratio of NiO-NP/PVP in the HIL 52 can be 60/40 or more and 95/5 or less. By setting the weight ratio of the NiO-NP 52a to the total amount of the NiO-NP 52a and the PVP 52b in the NiO-NP dispersion 71 to equal to or greater than 90.9 wt % and equal to or less than 96.4 wt %, the volume ratio of NiO-NP/PVP in the HIL 52 can be 60/40 or more and 80/20 or less.

Note that the weight ratio of NiO-NP/PVP in the NiO-NP dispersion 71 is maintained as it is even in the HIL 52. Therefore, the weight ratio (NiO-NP/PVP) of the NiO-NP 52a to the PVP 52b in the HIL 52 is the same as the weight ratio of NiO-NP/PVP in the NiO-NP dispersion 71.

As described above, for the purpose of controlling the volume ratio of NiO and PVP in the HIL 52 (film), it is necessary to prepare the mixture of liquids at the above-mentioned weight ratio in order to achieve the volume ratio.

In addition, the concentration (weight percent concentration) of the NiO-NP 52a in the NiO-NP dispersion 71 is not particularly limited as long as the concentration is set so as to obtain the HIL 52 having a desired layer thickness. However, from the viewpoint of controlling the layer thickness of the HIL 52, the concentration of the NiO-NP 52a in the NiO-NP dispersion 71 is desirably in a range from 5 mg/ml to 50 mg/ml.

Note that the volume median diameter (D50) of the NiO-NP 52a in the NiO-NP dispersion 71 is the same as the volume median diameter (D50) of the NiO-NP 52a in the HIL 52.

### (Manufacturing Method for Light-Emitting Element ES)

Next, a manufacturing method for the light-emitting element ES will be described.

A manufacturing method for a light-emitting element according to an aspect of the disclosure includes a step of forming the HIL 52 (HIL forming step). The HIL forming step includes a step of applying the NiO-NP dispersion 71 containing the NiO-NP 52a, the PVP 52b, and the solvent 72, and a step of removing the solvent 72 contained in the NiO-NP dispersion 71. In addition, the manufacturing method for a light-emitting element according to an aspect of the disclosure includes a step of preparing the NiO-NP dispersion 71 as a manufacturing method for the NiO-NP dispersion 71 before the step of applying the NiO-NP dispersion 71.

Hereinafter, a manufacturing method for a light-emitting element according to an aspect of the disclosure will be described with reference to a manufacturing method for the light-emitting element ES illustrated in FIG. 1 as an example.

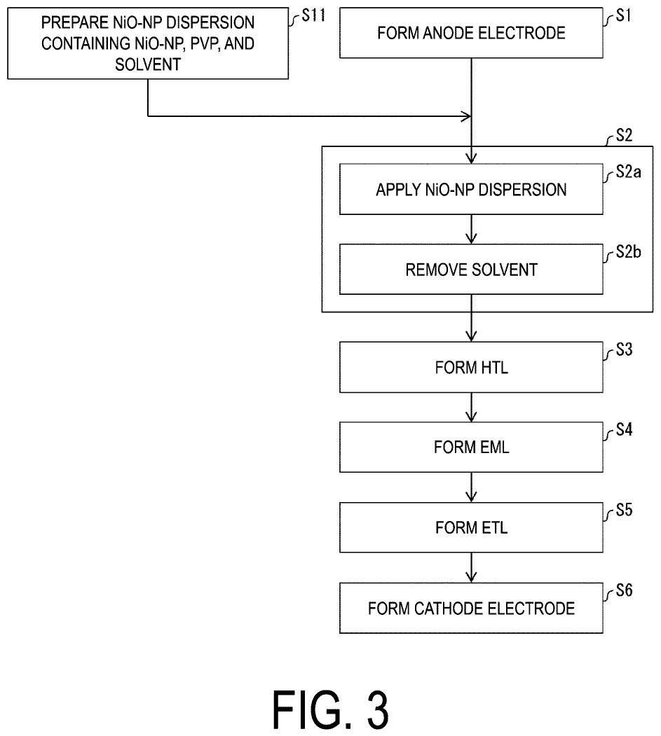

FIG. 3 is a flowchart illustrating an example of the manufacturing method for the light-emitting element ES according to the present embodiment.

As illustrated in FIG. 3, in the manufacturing method for the light-emitting element ES according to the present embodiment, the anode electrode 51 is formed on a substrate (not illustrated) (step S1, anode electrode forming step). On the other hand, the NiO-NP dispersion 71 illustrated in FIG. 2 is prepared (manufactured) (step S11, NiO-NP dispersion preparation step). Subsequently, the HIL 52 is formed using the NiO-NP dispersion 71 (step S2, HIL forming step). Note that step S11 is to be performed before step S2, and may be performed in parallel with step S1, may be performed between step S1 and step S2 (that is, after step S1 and before step S2), or may be performed before step S1.

Note that in step S11, it is desirable to mix the NiO-NP 52a with the PVP 52b so that the volume ratio of the NiO-NP 52a to the PVP 52b (NiO-NP/PVP) in the NiO-NP dispersion 71 becomes the volume ratio described above. To be specific, in step S11, it is desirable to mix the NiO-NP 52a with the PVP 52b so that the weight ratio of the NiO-NP 52a to the total amount of the NiO-NP 52a and the PVP 52b in the NiO-NP dispersion 71 becomes the above-described weight ratio.

In step S2, first, the NiO-NP dispersion 71 is applied onto the anode electrode 51 (step S2a, NiO-NP dispersion applying step). Thus, a coating film of the NiO-NP dispersion 71 is formed. Next, the solvent 72 contained in the coating film (that is, applied NiO-NP dispersion 71) is removed by heating or the like to dry the coating film (step S2b, solvent removal step).

Note that as described above, the NiO-NP dispersion 71 is applied by spin coating (spinner coating). The number of spin rotations may be appropriately set in accordance with the concentration of the NiO-NP 52a in the NiO-NP dispersion 71 and the like and is not particularly limited. As an example, in Examples described later, the NiO-NP dispersion 71 was applied at a spin rotation speed of 1200 rpm/30 sec, for example.

In addition, the solvent 72 contained in the coating film can be removed by baking the coating film. The drying conditions such as the baking temperature and the baking time may be appropriately set according to the kind of the solvent 72 contained in the NiO-NP dispersion 71, the concentration of the NiO-NP 52a in the NiO-NP dispersion 71, and the like, and are not particularly limited. As an example, in Examples to be described later, the coating film was dried after being baked at 200° C. for 15 minutes.

Next, the HTL 53 is formed (step S3). Next, the EML 54 is formed (step S4). Next, the ETL 55 is formed (step S5). Next, the cathode electrode 56 is formed (step S6).

Note that the method of forming each layer (the anode electrode 51, the HTL 53, the EML 54, the ETL 55, and the cathode electrode 56) except for the HIL 52 is the same as the known method. The anode electrode 51 and the cathode electrode 56 can be film-formed by, for example, a film deposition method, a sputtering method, an ink-jet method, or the like. The HTL 53 can be film-formed by, for example, a vacuum vapor deposition technique, a spin coating method, an ink-jet method, or the like. The ETL 55 can be film-formed by, for example, a spin coating method, an ink-jet method, or the like. The EML 54 can be formed by applying a QD dispersion containing the QD 54a and the solvent and then drying the QD dispersion. Note that the QD dispersion may contain a known ligand as a dispersing agent.

### Advantageous Effects

Next, the light-emitting element ES and the manufacturing method therefor described above, and the effects of the NiO-NP dispersion 71 will be described in more detail.

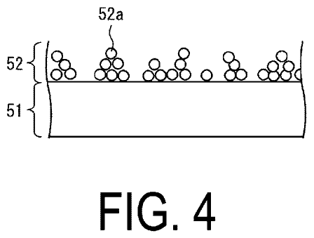

FIG. 4 is a cross-sectional view schematically illustrating the structure of the HIL 52 on the anode electrode 51 in a comparative light-emitting element in which the HIL 52 does not contain the PVP 52b.

As described above, the NiO-NP 52a tends to aggregate due to small particle size, and solvents and additives suitable for the NiO-NP 52a have not been found, and dispersibility in solvents is low. Therefore, the NiO-NP dispersion that does not contain the PVP 52b will be separated into two layers because the NiO-NP 52a is precipitated with the lapse of time. For this reason, when the HIL is formed by using the NiO-NP dispersion that does not contain the PVP 52b, it is necessary to prepare the NiO-NP dispersion immediately before the spinner coating and perform the spinner coating before the NiO-NP 52a is precipitated.

In addition, as described above, since the NiO-NP 52a tends to aggregate and has low dispersibility in the solvent when the PVP 52b is not used, stable film formation cannot be performed, and as illustrated in FIG. 4, unevenness is generated on the surfaces of the HIL 52. Thus, when the surfaces of the HIL 52 are uneven, not uniform, and not flat as described above, the movement of holes in the HIL 52 will be biased, and the light emission of the light-emitting element becomes uneven.

However, the PVP functions as a dispersing agent as described above. Therefore, since the NiO-NP dispersion 71 contains the PVP 52b, the NiO-NP 52a is not precipitated, and it is possible to provide the NiO-NP dispersion 71 that can be prepared in advance and stored.

Therefore, when the NiO-NP dispersion 71 contains the PVP 52b, the film formability of the HIL 52 can be improved as shown in Examples described later. For this reason, the flatness of the HIL 52 can be improved, the light-emitting element ES can uniformly emit light, and the hole injection property of the HIL 52 can be improved.

In addition, the PVP 52b does not adversely affect the light-emission characteristics. For this reason, it is possible not only to suppress a decrease in EQE but also to improve EQE compared with the case where the HIL 52 is made of NiO-NP alone depending on the addition amount.

In addition, as described above, the PVP 52b functions as a binder resin. The PVP 52b has high heat stability, and so the HIL 52 has high heat stability by including the PVP 52b, and it is possible to obtain the HIL 52 having a stronger and more stable film quality than the case where the HIL 52 is made of NiO-NP alone.

On the other hand, same as the PVP 52b, vinyl polymers such as polyvinyl alcohol are not suitable as a binder resin for the HIL 52. The HIL using polyvinyl alcohol as a binder resin has low heat stability and low reliability.

In addition, as described above, the method described in PTL 1 requires complicated and time-consuming processing. In addition, in PTL 1, as described above, a NiO precursor liquid or a previously produced NiO liquid containing a ligand as a dispersing agent is applied onto a substrate on which a conductive film is provided, and an annealing treatment is performed to form a NiO thin film. Then, in order to promote the chemical bonding between the organic molecules and the Ni atoms, before applying the organic molecule solution, for example, ultraviolet ozone treatment is performed to remove the ligands and expose the nickel atoms. Therefore, in PTL 1, although the film quality of the hole transport layer may be strengthened by promoting the bonding between the organic molecules and the nickel atoms by the ozone treatment, when a substrate having a bank made of an organic insulator is used as the substrate, there is a high possibility that the bank shape is deformed by the ozone treatment.

However, according to the present embodiment, as described above, the HIL 52 can be formed by applying the NiO-NP dispersion 71 containing the PVP 52b and then performing firing once. Further, ozone treatment is not required. Consequently, the manufacturing process of the HIL 52 can be simplified. Furthermore, it is also possible to use a substrate having a bank such as an edge cover covering the edge of the lower layer electrode. That is, the light-emitting element ES may include a bank such as an edge cover that covers the electrode, of the anode electrode 51 and the cathode electrode 56, on the lower layer side.

In addition, as described above, PVP may be dissolved in an aqueous solvent and in an organic solvent, and may also be dissolved in an ink solvent for an ink-jet coating device. Thus, according to the present embodiment, the HIL 52 can be easily formed.

Therefore, according to the present embodiment, it is possible to provide the light-emitting element ES and the manufacturing method for the light-emitting element ES that includes the HIL 52 having good film formability, an improved hole injection property, high flatness, and high strength, and can easily form such an HIL 52. Thus, according to the present embodiment, it is possible to provide a light-emitting element having high EQE in which a decrease in EQE is suppressed, further, a light-emitting element having improved EQE and higher EQE than known light-emitting elements, and a manufacturing method for the light-emitting element. In addition, according to the present embodiment, it is possible to provide the NiO-NP dispersion 71 capable of forming the above-described HIL 52.

Note that the light-emitting element ES may be used, for example, as a light source of a light-emitting device for a display device, an illumination device, or the like. Therefore, the light-emitting device according to an aspect of the disclosure may include the light-emitting element ES. As a result, it is possible to provide a light-emitting device that includes the HIL 52 having good film formability, an improved hole injection property, high flatness, and high strength, and can easily form such an HIL 52. Furthermore, it is also possible to use a substrate having a bank as the substrate of the light-emitting device. For example, when the light-emitting device is a display device, the display device may have a configuration in which a plurality of pixels are provided, the light-emitting element ES is provided in each pixel, and a bank is provided between adjacent pixels. In this case, the bank is used as a pixel separation film for partitioning adjacent pixels.

The bank such as an edge cover and a pixel separation film can be formed of, for example, a coatable photosensitive organic material such as a polyimide resin or an acrylic resin.

Next, a display device according to the present embodiment will be described. As described above, the light-emitting element ES may be used as a light source of a display device. A display device according to the present embodiment includes a plurality of the light-emitting elements ES according to the present embodiment.

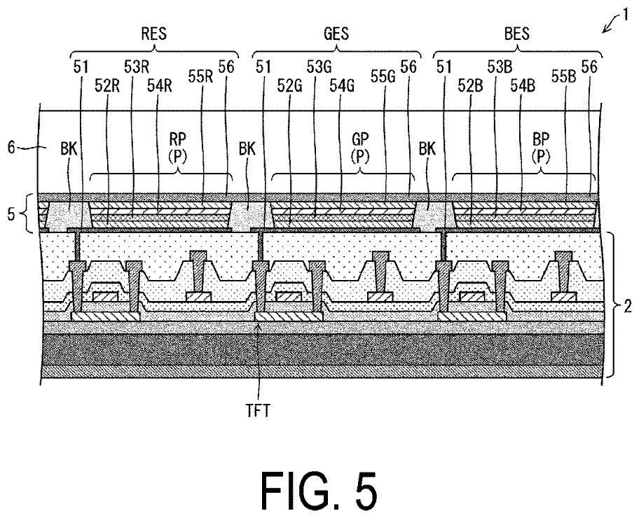

FIG. 5 is a cross-sectional view illustrating an example of a schematic configuration of main portions of the display device 1 according to the present embodiment.

The display device 1 includes a plurality of pixels P, as illustrated in FIG. 5. A light-emitting element ES is provided in each pixel P. The display device 1 illustrated in FIG. 5 includes, as a substrate 2, an array substrate formed with a drive element layer, and has a configuration in which a light-emitting element layer 5 including a plurality of light-emitting elements ES having different light emission wavelengths, and a sealing layer 6 covering the light-emitting element layer 5 are layered in this order on the substrate 2.

The display device 1 illustrated in FIG. 5 includes, as a pixel P, a pixel RP (red pixel) that emits red light, a pixel GP (green pixel) that emits green light, and a pixel BP (blue pixel) that emits blue light, for example. A bank BK with insulating properties that partitions adjacent pixels P to each other is provided as a pixel separation film between the pixels P.

The display device 1 includes a light-emitting element RES that emits red light (red light-emitting element), a light-emitting element GES that emits green light (green light-emitting element), and a light-emitting element BES that emits blue light (blue light-emitting element) as the plurality of light-emitting elements ES having different light emission wavelengths. In the pixel RP, the light-emitting element RES is provided as the light-emitting element ES. In the pixel GP, the light-emitting element GES is provided as the light-emitting element ES. In the pixel BP, the light-emitting element BES is provided as the light-emitting element ES.

The light-emitting element layer 5 includes the plurality of light-emitting elements ES respectively provided for each pixel P and has a structure in which each layer of these light-emitting elements ES is layered on the substrate 2.

Therefore, when the light-emitting element ES has, for example, the known structure as described above, the anode electrode 51, the HIL 52, the HTL 53, the EML 54, the ETL 55, and the cathode electrode 56 of each light-emitting element ES are layered on the substrate 2, for example, in this order from the lower layer side.

Although not illustrated, when the light-emitting element ES has an inverted structure, as described above, the cathode electrode 56, the ETL 55, the EML 54, the HTL 53, the HIL 52, and the anode electrode 51 are layered in this order from the lower layer side.

The substrate 2 functions as a support body for forming each layer of the light-emitting elements ES. A Thin Film Transistor (TFT) layer, for example, is formed at the substrate 2 as the drive element layer. The TFT layer is provided with a drive circuit, as a pixel circuit, which drives each light-emitting element ES and includes a drive element such as TFT.

The anode electrode 51, the HIL 52, the HTL 53, the EML 54, and the ETL 55 are each separated into an island shape for each pixel P by the bank BK as illustrated in FIG. 5. On the other hand, the cathode electrode 56, which is an upper layer electrode, is not separated by the bank BK and is formed as a common layer common to the pixels P. Therefore, in the present embodiment, the anode electrode 51 is a pattern anode electrode formed in an island-shaped pattern. The anode electrode 51 in each pixel P is electrically connected to each of the plurality of TFTs of the TFT layer. On the other hand, the cathode electrode 56 is a common cathode electrode common to all pixels P.

The light-emitting element RES illustrated in FIG. 5 includes the HIL 52R as the HIL 52, the HTL 53R as the HTL 53, the EML 54R as the EML 54, and the ETL 55R as the ETL 55. In addition, the light-emitting element GES illustrated in FIG. 5 includes the HIL 52G as the HIL 52, the HTL 53G as the HTL 53, the EML 54G as the EML 54, and the ETL 55G as the ETL 55. In addition, the light-emitting element BES illustrated in FIG. 5 includes the HIL 52B as the HIL 52, the HTL 53B as the HTL 53, the EML 54B as the EML 54, and the ETL 55B as the ETL 55.

Therefore, the light-emitting element RES illustrated in FIG. 5 has a configuration in which the anode electrode 51, the HIL 52R, the HTL 53R, the EML 54R, the ETL 55R, and the cathode electrode 56 are layered in this order from the substrate 2 side. In addition, the light-emitting element GES illustrated in FIG. 5 has a configuration in which the anode electrode 51, the HIL 52G, the HTL 53G, the EML 54G, the ETL 55G, and the cathode electrode 56 are layered in this order from the substrate 2 side. In addition, the light-emitting element BES illustrated in FIG. 5 has a configuration in which the anode electrode 51, the HIL 52B, the HTL 53B, the EML 54B, the ETL 55B, and the cathode electrode 56 are layered in this order from the substrate 2 side.

Note that as described above, the particle diameter of the NiO-NP 52a includes a particle diameter suitable for the luminescent color of the light-emitting material of the EML 54. Therefore, the volume-based median diameter (D50) of the NiO-NP 52a in the HIL 52R of the light-emitting element RES in the display device 1 is preferably in a range from 12 nm to 20 nm. In addition, the volume-based median diameter (D50) of the NiO-NP 52a in the HIL 52G of the light-emitting element GES is preferably in a range from 10 nm to 16 nm. In addition, the volume-based median diameter (D50) of the NiO-NP 52a in the HIL 52B of the light-emitting element BES is preferably in a range from 8 nm to 14 nm.

Note that the bank BK is used as a pixel separation film as described above and is also used as an edge cover for covering an edge of the patterned lower layer electrode. Thus, the edge of the anode electrode 51 is covered by the bank BK, as illustrated in FIG. 5.

The bank BK is formed by applying a coatable photosensitive organic material described above, and then, performing patterning by photolithography.

The light-emitting element layer 5 is covered by the sealing layer 6. The sealing layer 6 is transparent and includes, for example, a first inorganic sealing film, an organic sealing film, and a second inorganic sealing film in the order from the lower layer side (that is, the light-emitting element layer 5 side). However, the sealing layer 6 is not limited thereto, and the sealing layer 6 may be formed of a single layer of an inorganic sealing film or a layered body of five or more layers of an organic sealing film and an inorganic sealing film. In addition, the sealing layer 6 may be sealing glass, for example. Each of the light-emitting elements ES is sealed by the sealing layer 6, thereby making it possible to prevent water, oxygen, or the like from permeating into the light-emitting element ES.

Note that the inorganic sealing film is a transparent inorganic insulating film and can be constituted by, for example, a silicon oxide (SiOx) film, a silicon nitride (SiNx) film, a silicon oxynitride (SiNO) film, or a layered film of these, formed by CVD (chemical vapor deposition).

An organic sealing layer is a transparent organic film having a flattening effect and can be made of a coatable organic material such as acrylic resin. The organic sealing layer can be formed, for example, by ink-jet application, and a bank (not illustrated) for stopping droplets may be provided in the non-display region, referred to as a frame region, around the pixel region (display region) in which the plurality of pixels P are provided.

In addition, a function film, selected as appropriate depending on the application, is formed on the sealing layer 6. Examples of the function film include a function film having at least one of an optical compensation function, a touch sensor function, and a protection function, for example. Note that when the display device 1 is a solid display device (that is, an inflexible display device), a glass substrate such as a touch panel, a polarizer, or a cover glass may be provided instead of the function film.

As described above, the display device 1 according to the present embodiment includes the light-emitting element ES according to the present embodiment. Therefore, according to the present embodiment, it is possible to provide, as a light-emitting device, the display device 1 that includes a hole injection layer having good film formability, an improved hole injection property, high flatness, and high strength, and can easily form such a hole injection layer.

### EXAMPLES

Next, effects of the light-emitting element ES according to the present embodiment will be described through Examples and Comparative Examples. However, the light-emitting element ES according to the present embodiment is not limited to the following Examples.

### (EQE)

In the following Examples and Comparative Examples, the EQE (N_{φ(exe)}) was evaluated by the number of photons (Np) extracted from a cell per unit area prepared as a light-emitting element for evaluation with respect to the number of carriers (Ne) injected into the cell as shown in the following formula.

Np=λ/hc×P×1/S (1/m²)

Ne=I/e×1/S (1/m²)

N_{φ(exe)}=Np/Ne×100=(P×λ×e)/(hc×I)×100 (%)

Note that in the formula, I represents current (A), P represents light intensity (measured light quantity (W)), S represents cell area (element area (m²)), λ represents light-emission peak wavelength (m), e represents electron quantum (A·s), h represents Planck's constant (J·s), and c represents the speed of light (m·s⁻¹).

The current (I) was measured with a Model 2400 source meter manufactured by Keithley Instruments Inc. The light intensity (P) was measured with a light intensity meter (model number: BM-5A) manufactured by TOPCON TECHNOHOUSE CORPORATION. The area of the cell was set to 4×10⁻⁶ (m²). The light-emission peak wavelength (λ) was set to 536 (nm). Planck's constant was set to 6.626×10⁻³⁴ J·s. The electron quantum (e) was set to 1.602×10⁻¹⁹ A·s. The speed of light (c) was set to 2.998×10⁸ (m·s⁻¹).

### (Volume Ratio of PVP and NiO-NP in HIL)

In order to control the volume ratio of ZnO-NP and PVP to an arbitrary ratio in the HIL, as shown in the following Examples and Comparative Examples, a NiO-NP dispersion was prepared at an arbitrary ratio, and a cell was prepared using the dispersion. The volume ratio between PVP and NiO-NP in the HIL was calculated assuming that the density of NiO-NP was 6.67 [g/cm³] and the density of PVP was 1.2 [g/cm³].

### (Film Formability)

The film formability of the HIL was determined by measuring the layer thickness by atomic force microscopy (AFM) and obtaining the root mean square height (Rq). The root mean square height (Rq) represents a root mean square in a reference length and means a reference deviation of the surface roughness.

Note that in Table 1 which will be described later, the film formability “Outstanding” indicates that Rq is less than 3.5 nm. In addition, the film formability “Good” indicates that Rq is 3.5 nm or more and less than 5.5 nm. The film formability of “Fair” indicates that Rq is 5.5 nm or more.

### Example 1

First, an ITO substrate on which ITO was formed as an anode electrode was prepared and washed. On the other hand, NiO-NP having a median diameter (D50) of 14 nm, PVP, and water as a solvent were mixed at room temperature at a ratio of PVP 0.28 mg and water 3 mL relative to NiO-NP 30 mg, and NiO-NP and PVP were dispersed in water to prepare a NiO-NP dispersion having a concentration of 90.91 wt %.

Next, 100 μL of the NiO-NP dispersion was spin-coated on the ITO substrate at a spin rotation speed of 1200 rpm/30 sec, and then baked at 200° C. for 15 minutes to evaporate the water. Thus, the HIL having a layer thickness (design value) of 20 nm was formed. At this time, the film formability was visually confirmed.

Next, a solution obtained by dissolving (dispersing) TFB in chlorobenzene so as to be 8 mg/mL was applied on the HIL by spin coating, and then baked at 110° C. for 30 minutes to evaporate chlorobenzene. Thus, the HTL having a layer thickness (design value) of 30 nm was formed.

Next, a QD colloidal solution obtained by dispersing red QDs having a core/shell structure of Cd/Se in octane so as to be 20 mg/mL was spin-coated on the HTL, and then baked at 110° C. for 10 minutes to evaporate the solvent. Thus, the EML having a layer thickness (design value) of 20 nm was formed.

Next, a ZnO-NP dispersion obtained by dispersing a ZnO nanoparticle having a median diameter (D50) of 15 nm (hereinafter referred to as “ZnO-NP”) in ethanol so as to be 2.5 wt % was spin-coated on the EML, and then baked at 110° C. for 10 minutes to evaporate ethanol. Thus, the ETL having a layer thickness (design value) of 50 nm was formed.

Next, the cathode electrode having a layer thickness (design value) of 100 nm was formed on the ETL by vapor-depositing Al.

Thereafter, the layered body, in which the HIL to the cathode electrode were formed on the ITO substrate, was sealed with a cover glass. Thus, a cell as a light-emitting element for evaluation was fabricated. Next, EQE of the produced cell was obtained.

### Examples 2 to 8

The same operation as in Example 1 was performed except that the blending amounts of NiO-NP, PVP, and water were changed as shown in Table 1 below. Thus, a cell as a light-emitting element for evaluation was prepared, and then EQE of the prepared cell was obtained.

### Comparative Example 1

The same operation as in Example 1 was performed except that PVP was not added to NiO-NP. Thus, a cell as a light-emitting element for evaluation was prepared, and then EQE of the prepared cell was obtained.

In Examples 1 to 8 and Comparative Example 1, the volume ratio of NiO-NP and PVP in the HIL, the blending amount of NiO-NP, PVP and water in the NiO-NP dispersion, the concentration (weight percent concentration) of NiO-NP in the NiO-NP dispersion, the weight ratio of NiO-NP to the total amount of NiO-NP and PVP in the NiO-NP dispersion, the film formability of the HIL, and the EQE of the prepared cell are collectively shown in Table 1.

TABLE 1

| | | | NiO—NP dispersion | | | | | | |
|---|---|---|---|---|---|---|---|---|---|
| | | | | | | | Weight ratio [wt %] | | |
| | Volume ratio | | | | | NiO—NP | of NiO—NP to | | |
| | in HIL | | NiO—NP | PVP | Water | concentration | total amount of | Film | EQE |
| | ZnO—NP | PVP | [mg] | [mg] | [mg] | [wt %] | NiO—NP and PVP | formability | [%] |
| Comparative | 100 | 0 | 30 | 0 | 3 | 90.91 | — | Δ | 5.2 |
| Example 1 | | | | | | | | | |
| Example 1 | 95 | 5 | 30 | 0.28 | 3 | 90.14 | 0.92 | ◯ | 5.4 |
| Example 2 | 90 | 10 | 30 | 0.6 | 3 | 89.29 | 1.96 | ◯ | 5.5 |
| Example 3 | 80 | 20 | 30 | 1.12 | 3 | 87.92 | 5.60 | ⊚ | 5.9 |
| Example 4 | 70 | 30 | 30 | 1.93 | 3 | 85.89 | 6.04 | ⊚ | 5.8 |
| Example 5 | 60 | 40 | 30 | 3 | 3 | 83.33 | 9.09 | ⊚ | 5.6 |
| Example 6 | 50 | 50 | 30 | 4.5 | 3 | 80.00 | 13.04 | ⊚ | 5.2 |
| Example 7 | 40 | 60 | 30 | 8 | 4.5 | 70.59 | 21.05 | ⊚ | 5.1 |
| Example 8 | 30 | 70 | 30 | 12.5 | 5 | 63.16 | 29.41 | ⊚ | 4.6 |

As can be seen from Table 1, the addition of PVP to NiO-NP improves the film formability of the HIL. All of the cells obtained in Examples 1 to 8 were confirmed to emit light uniformly. In addition, according to Examples 1 to 8, it was confirmed that when the HIL contains PVP, the HIL having a strong and stable film quality can be obtained in any case.

Further, from the results shown in Table 1, it is found that the volume ratio of the NiO-NP 52a to the PVP 52b (NiO-NP/PVP) in the HIL 52 is desirably 40/60 or more and 95/5 or less. In addition, it is found that the volume ratio of NiO-NP/PVP in the HIL 52 is more desirably 80/20 or less from the viewpoint of film formability. From the viewpoint of EQE, it is found that the volume ratio of NiO-NP/PVP in the HIL 52 is more desirably 60/40 or more and 95/5 or less, and particularly desirably 60/40 or more and 80/20 or less.

Note that the volume ratio (NiO-NP/PVP) of the NiO-NP 52a to the PVP 52b in the HIL 52 is the same as the volume ratio (NiO-NP/PVP) of NiO-NP 52a to the PVP 52b in the NiO-NP dispersion 71. Therefore, from the results shown in Table 1, it is found that the volume ratio of NiO-NP 52a to the PVP 52b (NiO-NP/PVP) in the NiO-NP dispersion 71 is desirably 40/60 or more and 95/5 or less. In addition, it is found that the volume ratio of NiO-NP/PVP in the NiO-NP dispersion 71 is more desirably 80/20 or less from the viewpoint of film formability. In addition, from the viewpoint of EQE, it is found that the volume ratio of NiO-NP/PVP in the NiO-NP dispersion 71 is more desirably 60/40 or more and 95/5 or less, and particularly desirably 60/40 or more and 80/20 or less.

Further, from the results shown in Table 1, it is found that the weight ratio of the NiO-NP 52a to the total amount of the NiO-NP 52a and the PVP 52b in the NiO-NP dispersion 71 is desirably equal to or greater than 78.9 wt % and equal to or less than 99.1 wt %. In addition, it is found that the weight ratio of the NiO-NP 52a to the total amount of the NiO-NP 52a and the PVP 52b in the NiO-NP dispersion 71 is more desirably equal to or less than 96.4 wt % from the viewpoint of film formability. From the viewpoint of EQE, it is found that the weight ratio of the NiO-NP 52a to the total amount of the NiO-NP 52a and the PVP 52b in the NiO-NP dispersion 71 is more desirably equal to or greater than 90.9 wt % and equal to or less than 99.1 wt %, and particularly desirably equal to or greater than 90.9 wt % and equal to or less than 96.4 wt %.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
an anode electrode;
a cathode electrode;
a light-emitting layer provided between the anode electrode and the cathode electrode; and
a hole injection layer provided between the anode electrode and the light-emitting layer,
wherein the hole injection layer includes a nickel oxide nanoparticle, and polyvinylpyrrolidone.

2. The light-emitting element according to claim 1,
wherein a volume ratio of the nickel oxide nanoparticle to the polyvinylpyrrolidone in the hole injection layer is 40/60 or more and 95/5 or less.

3. The light-emitting element according to claim 2,
wherein a volume ratio of the nickel oxide nanoparticle to the polyvinylpyrrolidone in the hole injection layer is 80/20 or less.

4. The light-emitting element according to claim 1,
wherein a volume ratio of the nickel oxide nanoparticle to the polyvinylpyrrolidone in the hole injection layer is 60/40 or more and 95/5 or less.

5. The light-emitting element according to claim 1,
wherein a volume ratio of the nickel oxide nanoparticle to the polyvinylpyrrolidone in the hole injection layer is 60/40 or more and 80/20 or less.

6. The light-emitting element according to claim 1,
wherein a volume-based median diameter (D50) of the nickel oxide nanoparticle is in a range from 8 nm to 20 nm.

7. The light-emitting element according to claim 1,
wherein the light-emitting layer includes a quantum dot that emits red light, and
a volume-based median diameter (D50) of the nickel oxide nanoparticle is in a range from 12 nm to 20 nm.

8. The light-emitting element according to claim 1,
wherein the light-emitting layer includes a quantum dot that emits green light, and
a volume-based median diameter (D50) of the nickel oxide nanoparticle is in a range from 10 nm to 16 nm.

9. The light-emitting element according to claim 1,
wherein the light-emitting layer includes a quantum dot that emits blue light, and
a volume-based median diameter (D50) of the nickel oxide nanoparticle is in a range from 8 nm to 14 nm.

10. A display device comprising
a plurality of the light-emitting elements according to claim 1.

11. The display device according to claim 10,
wherein the plurality of light-emitting elements include:
a red light-emitting element in which the light-emitting layer includes a quantum dot that emits red light;
a green light-emitting element in which the light-emitting layer includes a quantum dot that emits green light;
a blue light-emitting element in which the light-emitting layer includes a quantum dot that emits blue light,
a volume-based median diameter (D50) of the nickel oxide nanoparticle in the red light-emitting element is in a range from 12 nm to 20 nm,
a volume-based median diameter (D50) of the nickel oxide nanoparticle in the green light-emitting element is in a range from 10 nm to 16 nm, and
a volume-based median diameter (D50) of the nickel oxide nanoparticle in the blue light-emitting element is in a range from 8 nm to 14 nm.

12. A nickel oxide nanoparticle dispersion, comprising:
a nickel oxide nanoparticle;
polyvinylpyrrolidone; and
a solvent,
wherein a volume-based median diameter (D50) of the nickel oxide nanoparticle is in a range from 8 nm to 20 nm.

13. The nickel oxide nanoparticle dispersion according to claim 12,
wherein a volume ratio of the nickel oxide nanoparticle to the polyvinylpyrrolidone is 40/60 or more and 95/5 or less.

14. (canceled)

15. The nickel oxide nanoparticle dispersion according to claim 12,
wherein the solvent is an amphoteric solvent.

16. The nickel oxide nanoparticle dispersion according to claim 12,
wherein the nickel oxide nanoparticle dispersion is a dispersion for forming a hole transport layer in a light-emitting element.

17. A manufacturing method for a light-emitting element including an anode electrode, a cathode electrode, a light-emitting layer provided between the anode electrode and the cathode electrode, and a hole injection layer provided between the anode electrode and the light-emitting layer, the method comprising:
forming the hole injection layer,
wherein the forming the hole injection layer includes:
applying a nickel oxide nanoparticle dispersion containing a nickel oxide nanoparticle, polyvinylpyrrolidone, and a solvent; and
removing the solvent contained in the nickel oxide nanoparticle dispersion,
wherein the nickel oxide nanoparticle that has a volume-based median diameter (D50) in a range from 8 nm to 20 nm is used.

18. The manufacturing method for a light-emitting element according to claim 17,
wherein the nickel oxide nanoparticle is mixed with the polyvinylpyrrolidone at a volume ratio of 40/60 or more and 95/5 or less in preparing the nickel oxide nanoparticle dispersion.

19. (canceled)
